(19) United States
(12) Patent Application Publication
(10) Pub. No.: US 2018/0149112 A1
(43) Pub. Date: May 31, 2018

(54) HEAT EXCHANGER FOR A MOTOR VEHICLE

(71) Applicant: Mahle International GmbH, Stuttgart (DE)

(72) Inventors: Fahmi Ben Ahmed, Stuttgart (DE); Klaus Luz, Herrenberg (DE); Matthias Ganz, Stuttgart (DE); Holger Schroth, Maulbronn (DE)

(21) Appl. No.: 15/825,076

(22) Filed: Nov. 28, 2017

(30) Foreign Application Priority Data
Nov. 29, 2016 (DE) 10 2016 223 703.9

(51) Int. Cl. F02G 5/02; F01N 3/02; F01N 5/02; H01L 35/30; F01N 1/16

(52) U.S. Cl. CPC F02G 5/02; F01N 3/0205; F01N 5/025; H01L 35/30; F01N 2470/00; F01N 2240/36; F01N 2240/02; F01N 2240/40; F01N 1/165

(57) ABSTRACT

A heat exchanger for a motor vehicle may include an outer pipe through which hot gas may flow, the outer pipe extending along a longitudinal direction, defining an outer pipe interior, and including two outer pipe walls in a cross section perpendicular to the longitudinal direction. The heat exchanger may also include an inner pipe arranged in the outer pipe interior, the inner pipe extending along the longitudinal direction, being closed on a first longitudinal end, defining an inner pipe interior, and including two inner pipe walls in the cross section. The inner pipe walls may include a plurality of apertures by which the inner and outer pipe interiors may communicate fluidically. The heat exchanger may further have a plurality of thermoelectric modules arranged on an outer side of the outer pipe walls, each having a hot side facing the outer pipe and a cold side facing away from the outer pipe, and at least one coolant pipe through which a coolant may flow and which is arranged on the cold side of at least one thermoelectric module.

### CROSS-REFERENCE TO RELATED APPLICATIONS

This application claims priority to German Patent Application No. DE 10 2016 223 703.9, filed on Nov. 29, 2016, the contents of which are incorporated herein by reference in their entirety.

### TECHNICAL FIELD

The invention relates to a heat exchanger, in particular an exhaust gas heat exchanger, for a motor vehicle. The invention further relates to a motor vehicle comprising an internal combustion engine, comprising an exhaust gas system and such a heat exchanger, which cooperates with the exhaust gas system.

### BACKGROUND

Heat exchangers are used in connection with exhaust gas systems of internal combustion engines, in order to harness the heat contained in the exhaust gas. For this purpose, thermoelectric modules can be provided with thermoelectric elements in the heat exchanger. Such thermoelectric elements consist of thermoelectric semiconductor materials, which convert a temperature difference into a potential difference, thus into an electric voltage, and vice versa. The heat exchanger can convert heat energy into electrical energy in this way. Physically, the thermoelectric modules are based on the Seebeck effect, when they convert heat into electrical energy. Inside a thermoelectric module, p-doped and n-doped thermoelectric elements are interconnected. Typically, a plurality of such thermoelectric modules are interconnected to a thermoelectric generator, which can generate electrical energy or an electric voltage, respectively, from a temperature difference in connection with a corresponding heat flow. The temperature difference between the hot sides and the cold sides of the thermoelectric modules required for generating electrical energy is generated in the heat exchanger, in that the hot gas is brought into thermal interaction with the hot sides and a coolant is brought into thermal interaction with the cold sides of the thermoelectric modules with temperatures, which are lower as compared to the hot gas. This is successful in that the hot and cold sides of the thermoelectric modules are suitably arranged in the heat exchanger, through which the hot gas and the coolant flows.

### SUMMARY

The invention at hand deals with the problem of specifying an improved or at least a different embodiment, which is characterized by an improved efficiency, for a heat exchanger of the above-described type.

This object is solved by means of the subject matter of the independent patent claims. Preferred embodiments are the subject matter of the dependent patent claims.

It is thus the general idea of the invention to arrange thermoelectric modules comprising thermoelectric elements in a heat exchanger in such a way that the hot gas guided through the heat exchanger impacts the hot sides of the thermoelectric modules in the form of an impact jet. As a result, a particularly large amount of heat is extracted from the hot gas, which can be converted into electrical energy by the thermoelectric modules, following the operating principle of a thermoelectric generator. An improved efficiency of the heat exchanger is associated therewith, which proves to be advantageous in particular when said heat exchanger is operated as exhaust gas heat exchanger, in order to harness the energy contained in the exhaust gas of an internal combustion engine.

A heat exchanger according to the invention, which can preferably be used as exhaust gas heat exchanger, comprises an outer pipe for hot gas to flow through, which extends along a longitudinal direction and which defines an outer pipe interior and which, for this purpose, comprises two outer pipe pipe walls in a cross section perpendicular to the longitudinal direction. An inner pipe for the hot gas to flow through, which extends along the longitudinal direction and which defines an inner pipe interior, is arranged in the outer pipe interior, preferably coaxially to the outer pipe. The inner pipe is embodied so as to be closed on a longitudinal end and comprises two inner pipe pipe walls in the cross section perpendicular to the longitudinal direction. A plurality of apertures, which is present in the inner pipe pipe walls, is to be considered to be significant for the invention. The inner pipe interior communicates fluidically with the outer pipe interior by means of said apertures. The heat exchanger according to the invention furthermore comprises a plurality of thermoelectric modules, which are arranged on an outer side of the outer pipe pipe walls. The thermoelectric modules in each case have a hot side, which faces the outer pipe, and a cold side, which faces away from the outer pipe. The heat exchanger furthermore comprises at least one coolant pipe for a coolant to flow through, which is arranged on the cold side of at least one thermoelectric module.

By means of the above-described embodiment or arrangement according to the invention respectively, of outer pipe and inner pipe as well as the outer pipe or inner pipe pipe walls, respectively, with a cross section perpendicular to the longitudinal direction, it is attained that the hot gas, which flows through the inner pipe, can only reach into the outer pipe in a direction at right angle to the longitudinal direction through the apertures, which are present in the inner pipe pipe walls, and impacts the outer pipe pipe walls there. An advantageous, high dynamic pressure is thereby generated in the interior in the hot gas. As a result, a high impact effect of the hot gas is attained, when, after passing through the apertures, the hot gas impacts the outer pipe pipe walls of the outer pipe, on which the hot sides of the thermoelectric modules are arranged on the outer side. The desired, improved interaction of the hot gas with the thermoelectric modules is attained in this way, so that a particularly large amount of heat is extracted from the hot gas. As a result, the thermoelectric modules, which act as thermoelectric generators, generate correspondingly more electrical energy, which, in turn, increases the efficiency of the heat exchanger.

According to a preferred embodiment, the outer pipe is embodied as flat pipe. In the cross section perpendicular to the longitudinal direction, the two outer pipe pipe walls are located opposite one another and form the two broad sides of the flat pipe. In this alternative, at least a first thermoelectric module is arranged on the first outer pipe pipe wall and at least a second thermoelectric element is arranged on the second outer pipe pipe wall.

In the case of a further preferred embodiment, the inner pipe is embodied as flat pipe. In the case of this embodiment, the two inner pipe pipe walls are located opposite one another with a cross section perpendicular to the longitudinal direction and form the two broad sides of the flat pipe. The apertures are thereby arranged in the first inner wall pipe wall and in the second inner wall pipe wall. This alternative also supports the realization of the heat exchanger in flat design, in particular when the outer pipe is also realized as flat pipe.

Advantageously, the first outer pipe pipe wall can face the first inner pipe pipe wall in the cross section perpendicular to the longitudinal direction, and the second outer pipe pipe wall can face the second inner pipe pipe wall. The installation space of the heat exchanger can be kept particularly small in this way.

In the case of an advantageous further development, at least a first and at least a second coolant pipe are present. In the case of this further development, the at least one first coolant pipe is arranged on the cold side of the at least one first thermoelectric module. The at least one second coolant pipe is arranged on the cold side of the at least one second thermoelectric module. This allows for an even thermal contact of the coolant, which flows through the coolant pipes, with the thermoelectric modules of the heat exchanger.

Particularly preferably, the outer pipe is arranged between the first and the second coolant pipe along a stack direction, which runs at right angles to the longitudinal direction of the outer pipe. The installation space required in stack direction for the heat exchanger can be kept small in this way.

Particularly preferably, the at least one, in particular first and/or second coolant pipe is embodied as flat pipe, the broad sides of which in the cross section perpendicular to the longitudinal direction faces the (first or second) thermoelectric modules. This embodiment requires particularly little installation space along a direction of the outer pipe at right angles to the longitudinal direction thereof. At the same time, a flat contact of the coolant pipes with the cold sides of the thermoelectric modules can be attained by means of such flat pipes, whereby a high efficiency of the heat exchanger can be attained, in turn.

Advantageously, the first and/or second coolant pipe can in each case have a U-shaped geometry comprising a base and a first and a second leg. The two legs thereby extend along the longitudinal direction of the outer pipe. Coolant inlet and coolant outlet can be arranged on the same longitudinal end of the outer pipe in this way, which can be a considerable advantage in the case of certain installation space situations.

In the case of another advantageous further development, a coolant distributor is present on a first longitudinal end of the outer pipe. This coolant distributor communicates fluidically with a coolant inlet of the first and of the second coolant pipe, which is present on the first leg. In the alternative or in addition, a coolant collector is present on the first longitudinal end of the outer pipe in the case of this further development. Said coolant collector communicates fluidically with a coolant inlet of the first and of the second coolant pipe, which is present on the second leg. Coolant inlet and coolant outlet can be arranged on different longitudinal ends of the outer pipe in this way, which can be advantageous in the case of certain installation space situations.

In the case of a further preferred embodiment, the outer pipe is embodied so as to be closed on its two longitudinal ends, which are located opposite one another along the longitudinal direction. In the case of an alternative, preferred embodiment, the outer pipe is embodied so as to be open on one of the two longitudinal ends and is embodied so as to be closed on the other one of the two longitudinal ends. Both alternatives allow for an advantageous discharge of the hot gas from the heat exchanger.

On a second longitudinal end of the inner pipe, which is located opposite the first longitudinal end, a gas inlet for introducing the hot gas into the inner pipe, can advantageously connect to said second longitudinal end.

In the case of a further preferred embodiment, the flat pipe, which forms the outer pipe, has two narrow sides in the cross section perpendicular to the longitudinal direction. In the case of this embodiment, the side ratio of a broad side to a narrow side is more than 1, preferably at least 2, maximally preferably at least 4.

In the case of a further preferred embodiment, the flat pipe, which forms the inner pipe, has two narrow sides in the cross section perpendicular to the longitudinal direction. In the case of this embodiment, the side ratio of a broad side to a narrow side is more than 1, preferably at least 2, maximally preferably at least 6.

The invention furthermore relates to a heat exchanger arrangement comprising at least two heat exchangers, which are arranged on top of one another, which can preferably be stacked on top of one another. The heat exchangers of the heat exchanger arrangement communicate fluidically with one another via a common gas outlet. The advantages of the heat exchanger described above can thus also be transferred to the heat exchanger arrangement according to the invention.

The invention further relates to a motor vehicle comprising an internal combustion engine comprising an exhaust gas system and an above-introduced heat exchanger according to the invention. The above-described advantages of the heat exchanger can thus also be transferred to the motor vehicle according to the invention.

Further important features and advantages of the invention follow from the subclaims, from the drawings, and from the corresponding figure description by means of the drawings.

It goes without saying that the above-mentioned features and the features, which will be described below, cannot only be used in the respective specified combination, but also in other combination or alone, without leaving the scope of the invention at hand.

Preferred exemplary embodiments of the invention are illustrated in the drawings and will be described in more detail in the description below, whereby identical reference numerals refer to identical or similar or functionally identical components.

### BRIEF DESCRIPTION OF THE DRAWINGS

In each case schematically:

FIG. 1 shows an example of a heat exchanger embodied as exhaust gas heat exchanger in a longitudinal section,

FIG. 2 shows the heat exchanger of FIG. 1 in a cross section perpendicular to the longitudinal direction of the heat exchanger,

FIG. 3 shows a section through a U-shaped coolant pipe of the heat exchanger,

FIG. 4 shows an alternative of the heat exchanger according to FIGS. 1 and 2, in the case of which the coolant pipes do not extend in the longitudinal direction, as in the case of the example of FIG. 1, but at right angles.

### DETAILED DESCRIPTION

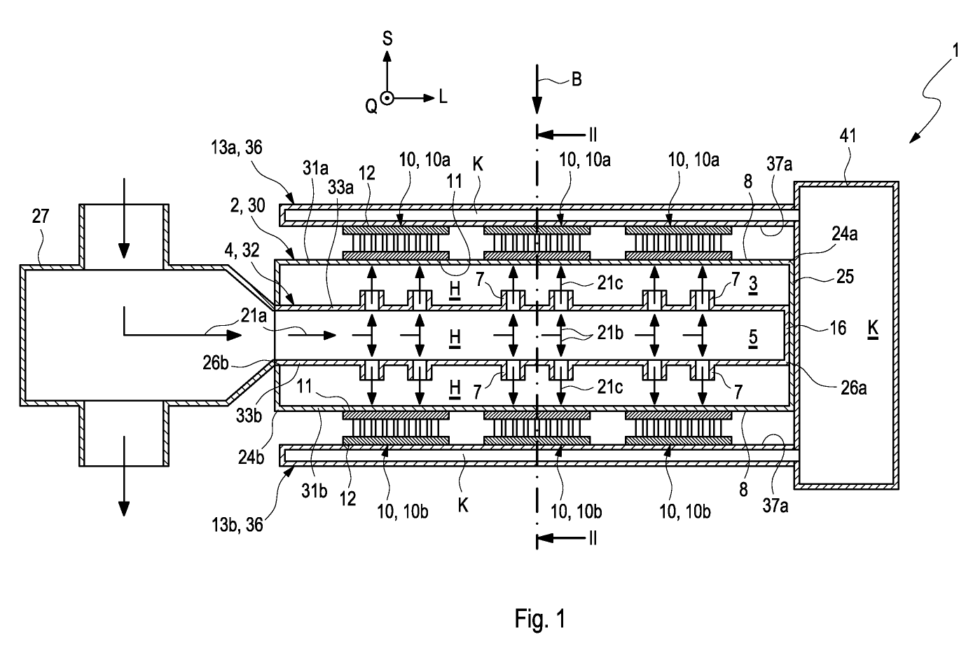

FIG. 1 shows, schematically, an example of a heat exchanger 1, which is embodied as exhaust gas heat exchanger. According to FIG. 1, the heat exchanger 1 has an outer pipe 2 for a hot gas H to flow through, which extends along a longitudinal direction L and which defines an outer pipe interior 3. An inner pipe 4, through which the hot gas H can likewise flow, and which defines an inner pipe interior 5, is arranged in the outer pipe interior 3.

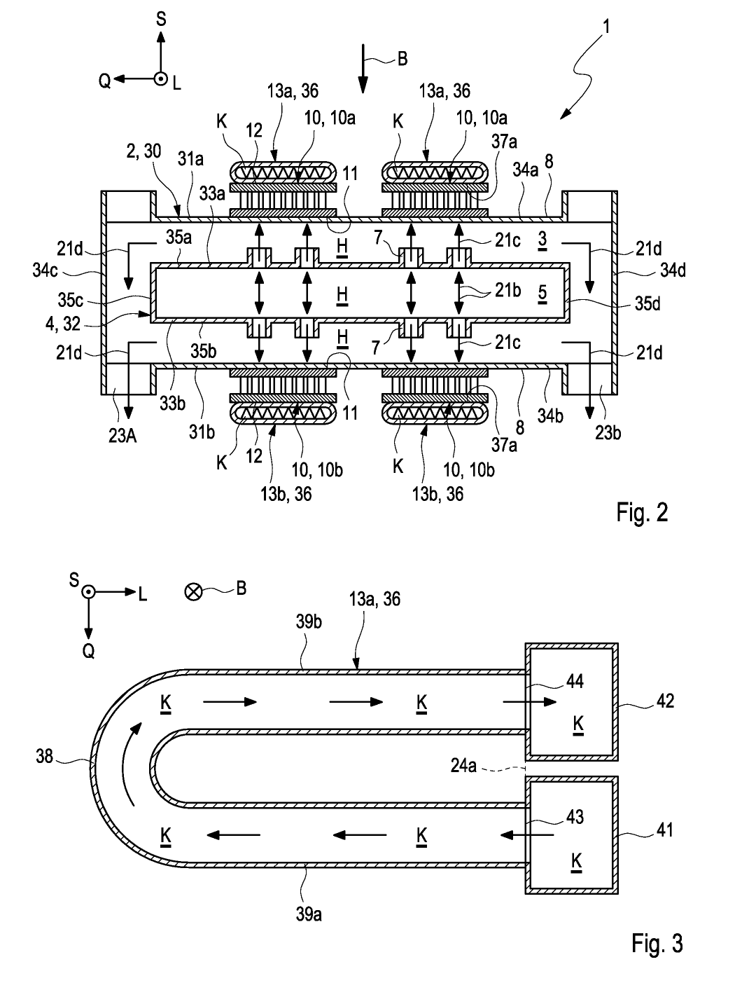

The outer pipe 2 is embodied as flat pipe 30 comprising a first outer pipe pipe wall 31a and a second outer pipe pipe wall 31b, which is located opposite the first outer pipe pipe wall 31a. According to FIGS. 1 and 2, a portion of the thermoelectric modules 10—hereinafter referred to as “first thermoelectric elements 10a”—are arranged on the outer side 8 of the first outer pipe pipe wall 31a. The remaining thermoelectric elements 10—hereinafter referred to as “second thermoelectric elements 10b”—are arranged on the outer side 8 of the second outer pipe pipe wall 31b. The inner pipe 4 is also embodied as flat pipe 32 comprising a first inner pipe pipe wall 33a and a second inner pipe pipe wall 33b located opposite the first inner pipe pipe wall 33a.

FIG. 2 shows the heat exchanger 1 from FIG. 1 in a cross section perpendicular to the longitudinal direction L along the sectional line II-II of FIG. 1. It can be seen that in the cross section perpendicular to the longitudinal direction L, the two outer pipe pipe walls 31a, 31b in each case form a broad side 34a, 34b of the outer pipe 2, which is realized as flat pipe 30. The flat pipe 30, which forms the outer pipe 2, furthermore has two narrow sides 34c, 34d in the cross section perpendicular to the longitudinal direction L. The side ratio of one of the two broad sides 34a, 34b to one of the two narrow sides 34c, 34d is more than 1, preferably at least 2, maximally preferably at least 4.

In the cross section perpendicular to the longitudinal direction L, the two inner pipe pipe walls 33a, 33b in each case form a broad side 35a, 35b of the inner pipe 4, which is realized as flat pipe 32. In the cross section perpendicular to the longitudinal direction L, the flat pipe 32, which forms the inner pipe 4, furthermore has two narrow sides 35c, 35d. The side ratio of one of the two broad sides 35a, 35b to one of the two narrow sides 35c, 35d is more than 1, preferably at least 2, maximally preferably at least 6.

According to FIG. 2, the first outer pipe pipe wall 31a faces the first inner pipe pipe wall 33a in the cross section perpendicular to the longitudinal direction L. Accordingly, the second outer pipe pipe wall 31b faces the second inner pipe pipe wall 33b.

In the example of FIGS. 1 and 2, the heat exchanger 1 furthermore comprises a first coolant pipe 13a and a second coolant pipe 13b for a coolant K to flow through, which has a lower temperature than the hot gas H. The coolant pipes 13a, 13b are thus arranged on the cold sides 12 of the thermoelectric modules 10, so that the coolant K, which flows through the coolant pipes 13, can thermally couple to the cold sides 12 of the thermoelectric modules 10.

The first coolant pipe 13a is arranged on the cold sides 12 of the first thermoelectric modules 10a. The second coolant pipe 13b is arranged on the cold sides 12 of the second thermoelectric modules 10b. The outer pipe 2 is thereby arranged between the first and the second coolant pipe 13a, 13b along a stack direction S, which runs at right angles to the longitudinal direction L of the outer pipe 2. The installation space required for the heat exchanger 1 in the stack direction S can be kept small in this way. The coolant pipes 13a, 13b can in each case also be embodied as flat pipes 36, the broad sides 37a of which face the first or second thermoelectric modules 10a, 10b, respectively, in the cross section perpendicular to the longitudinal direction L.

On a first longitudinal end 26a, the inner pipe 4 is embodied so as to be closed. For this purpose, the inner pipe has a front wall 16. On a second longitudinal end 26b of the inner pipe 4, which is located opposite the first longitudinal end 26a, however, a gas inlet 27 for introducing the hot gas H into the inner pipe 4 connects to the inner pipe 4. In other words, the inner pipe 4 is embodied so as to be open on the second longitudinal end 26b. In the first inner wall pipe wall 33a and in the second inner wall pipe wall 33b of the inner pipe 4, a plurality of apertures 7 is embodied in each case, by means of which the inner pipe interior 5 communicates fluidically with the outer pipe interior 3. The hot gas H, which flows through the outer pipe 2, can be thermally coupled to the hot sides 11 of the thermoelectric modules 10 in this way.

FIG. 3 shows a top view onto the coolant pipe 13a in a viewing direction B, which is suggested by means of an arrow in FIG. 1, which extends perpendicular to the longitudinal direction L and which runs opposite to the stack direction S. In the example of FIG. 3, the first coolant pipe 13a has a U-shaped geometry comprising a base 38 and a first and a second leg 39a, 39b. The two legs 39a, 39b extend along the longitudinal direction L of the outer pipe 2. On a first longitudinal end 24a (see FIG. 1) of the outer pipe 2, a coolant distributor 41 is present, which communicates fluidically with a coolant inlet 43 of the first coolant pipe 13, which is present on the first leg 39a. A coolant collector 42, which fluidically communicates with a coolant outlet 44 of the first coolant pipe 13a, which is present on the second leg 39b, is likewise present on the first longitudinal end 24a of the outer pipe 2. The two coolant pipes 13a, 13b can be embodied as identical parts. In this case, the second coolant pipe 13b is likewise embodied as shown in FIG. 3.

The flow-through of the heat exchanger 1 with hot gas H will be described below by means of FIG. 1. Via the gas inlet 27, the hot gas H is introduced into the inner pipe interior 5, which is defined by the inner pipe 4, and flows through said inner pipe interior along the longitudinal direction L (see arrows 21a). Due to the fact that the inner pipe interior 5 is defined by the front wall 16 of the inner pipe 4 in the longitudinal direction L, the hot gas H can only leave the inner pipe interior 5 along the stack direction S, thus at right angles to the longitudinal direction L, through the apertures 7, which are embodied in the first or second inner pipe pipe wall 33a, 33b, respectively (see arrows 21b). Due to the dynamic pressure, which forms in the inner pipe interior 5 in the hot gas H, the hot gas H is accelerated while flowing through the apertures 7 and in each case impacts the first or second outer pipe pipe wall 31a, 13b, respectively, of the outer pipe 2, in the form of an impact jet (see arrows 21c). Thermal energy is thereby emitted to the thermoelectric modules 10. The hot gas H, which bounces off the outer pipe pipe walls 31a, 31b, thus reflected hot gas, can leave the heat exchanger 1 (see arrows 21d) through two gas outlets 23a, 23b (see FIG. 2), which are present on the outer pipe 2 and which extend along the stack direction S. In the scenario of FIGS. 1 and 2, the outer pipe 2 is embodied so as to be closed on one of two longitudinal ends 24a, 24b, which are located opposite one another along the longitudinal direction. The outer pipe 2 is thereby closed by means of a front wall 25. This allows for an advantageous discharge of the hot gas H in the outer pipe 2 in two directions opposite one another (see arrows 21c, 21d in FIG. 2), which is known to the pertinent person of skill in the art as “medium crossflow”.

A heat exchanger arrangement comprising two heat exchangers 1, which are arranged on top of one another, can be formed from the above-described heat exchanger 1. The heat exchangers 1 can preferably be stacked on top of one another along the stack direction S (see FIG. 2) and can fluidically communicate with one another by means of the two gas outlets 23a, 23b. FIG. 2 thus shows a single heat exchanger 1 of such a heat exchanger arrangement.

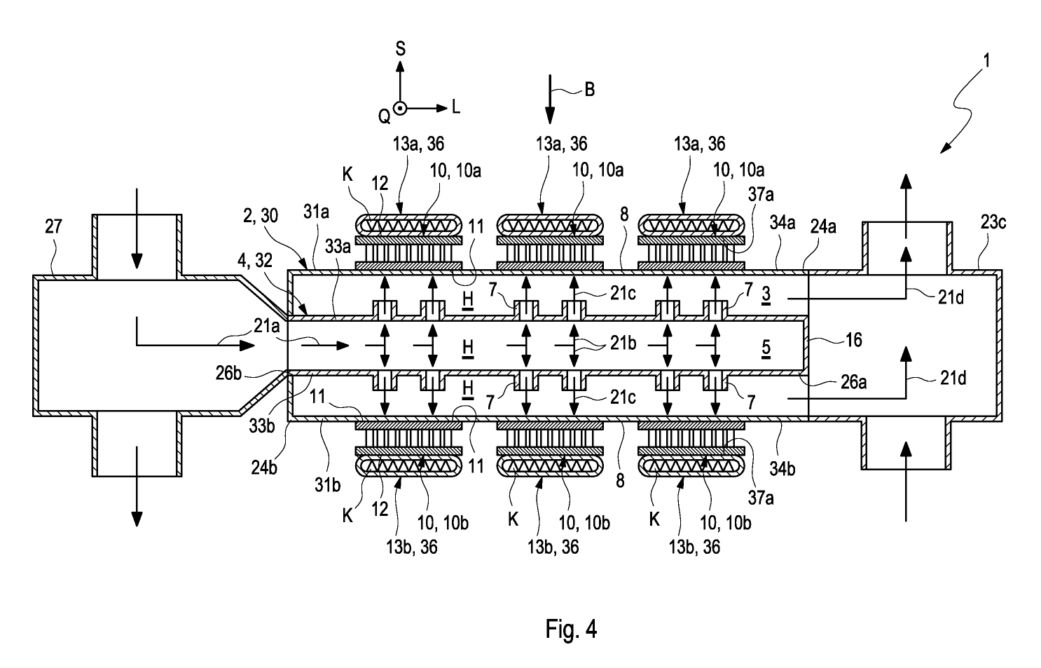

FIG. 4 illustrates an alternative of the example of FIG. 1, in the case of which the outer pipe 2 is embodied so as to be open on the longitudinal end 24a for discharging the hot gas H. This allows for an advantageous discharge of the hot gas H in only one direction (see arrows 21d in FIG. 4) via a gas outlet 23c, which connects to the outer pipe 2 on the first longitudinal end 24a. This scenario is known to the pertinent person of skill in the art as “maximum crossflow”.

In an alternative, which is not shown in more detail in the figures, the alternatives “maximum crossflow” and “medium crossflow” can also be combined.

The heat exchanger 1 according to FIG. 4 has three first coolant pipes 13a and three second coolant pipes 13b. In alternatives, the number of first and second coolant pipes 13a, 13b can vary. According to FIG. 4, the first and second coolant pipes 13a, 13b are in each case arranged at a distance to one another along the longitudinal direction L and in each case extend along a transverse direction Q, which runs perpendicular to the longitudinal direction L as well as to the stack direction S.

1. A heat exchanger for a motor vehicle, comprising:
an outer pipe through which hot gas is flowable, the outer pipe extending along a longitudinal direction, defining an outer pipe interior, and including two outer pipe walls in a cross section perpendicular to the longitudinal direction;
an inner pipe arranged in the outer pipe interior, extending along the longitudinal direction, being closed on a first longitudinal end, defining an inner pipe interior, and including two inner pipe walls in the cross section perpendicular to the longitudinal direction;
a plurality of apertures in the inner pipe walls by which the inner pipe interior communicates fluidically with the outer pipe interior;
a plurality of thermoelectric modules arranged on an outer side of the outer pipe walls, each thermoelectric module having a hot side, which faces the outer pipe, and a cold side, which faces away from the outer pipe; and
at least one coolant pipe through which a coolant is flowable and which is arranged on the cold side of at least one thermoelectric module.

2. The heat exchanger according to claim 1, wherein:
the outer pipe is a flat pipe; and
in the cross section perpendicular to the longitudinal direction, the two outer pipe walls are located opposite one another and form two broad sides of the flat pipe.

3. The heat exchanger according to claim 1, wherein:
the inner pipe is a flat pipe;
in the cross section perpendicular to the longitudinal direction, the two inner pipe walls are located opposite one another and form two broad sides of the flat pipe; and
the apertures are arranged in a first inner pipe wall and a second inner pipe wall of the two inner pipe walls.

4. The heat exchanger according to claim 3, wherein a first outer pipe wall of the two outer pipe walls faces the first inner pipe wall in the cross section perpendicular to the longitudinal direction, and a second outer pipe wall of the two outer pipe walls faces the second inner pipe wall.

5. The heat exchanger according to claim 1, wherein:
the at least one coolant pipe includes at least a first coolant pipe and at least a second coolant pipe; and
wherein the at least one first coolant pipe is arranged on the cold side of the at least a first thermoelectric module, and the at least one second coolant pipe is arranged on the cold side of at least a second thermoelectric module.

6. The heat exchanger according to claim 1, the outer pipe is arranged between a first coolant pipe and a second coolant pipe along a stack direction, which runs at right angles to the longitudinal direction of the outer pipe.

7. The heat exchanger according to claim 1, wherein the at least one coolant pipe is a flat pipe with a broad side, which in the cross section perpendicular to the longitudinal direction faces one of the thermoelectric modules.

8. The heat exchanger according to claim 5, wherein:
at least one of the first coolant pipe and the second coolant pipe has a U-shaped geometry including a base, a first leg, and a second leg; and
the first leg and the second leg extend along the longitudinal direction of the outer pipe.

9. The heat exchanger according to claim 8, further comprising:
a coolant distributor on a first longitudinal end of the outer pipe, the coolant distributor communicating fluidically with a coolant inlet of the first coolant pipe and of the second coolant pipe, the coolant inlet being present on the first leg; and
a coolant collector on the first longitudinal end of the outer pipe, the coolant collector communicating fluidically with a coolant outlet of the first coolant pipe and of the second coolant pipe, the coolant outlet being present on the second leg.

10. The heat exchanger according to claim 1, wherein the outer pipe is closed on two longitudinal ends located opposite one another along the longitudinal direction.

11. The heat exchanger according to claim 1, wherein the outer pipe closed on one longitudinal end and open on another longitudinal end for discharging the hot gas.

12. The heat exchanger according to claim 1, wherein on a second longitudinal end of the inner pipe, which is located opposite the first longitudinal end, a gas inlet for introducing the hot gas into the inner pipe connects to said second longitudinal end.

13. The heat exchanger according to claim 2, wherein:
the flat pipe, which forms the outer pipe, has two narrow sides in the cross section perpendicular to the longitudinal direction; and
a side ratio of a broad side to a narrow side is more than 1.

14. The heat exchanger according to claim 3, wherein
the flat pipe, which forms the inner pipe, has two narrow sides in the cross section perpendicular to the longitudinal direction; and
a side ratio of a broad side to a narrow side is more than 1.

15. A heat exchanger arrangement comprising at least two heat exchangers arranged on top of one another, each heat exchanger including:
an outer pipe through which hot gas is flowable, the outer pipe extending along a longitudinal direction, defining an outer pipe interior, and including two outer pipe walls in a cross section perpendicular to the longitudinal direction;
an inner pipe arranged in the outer pipe interior, extending along the longitudinal direction, being closed on a first longitudinal end, defining an inner pipe interior, and including two inner pipe walls in the cross section perpendicular to the longitudinal direction;
a plurality of apertures in the inner pipe walls by which the inner pipe interior communicates fluidically with the outer pipe interior;
a plurality of thermoelectric modules arranged on an outer side of the outer pipe walls, each thermoelectric module having a hot side, which faces the outer pipe, and a cold side, which faces away from the outer pipe; and
at least one coolant pipe through which a coolant is flowable and which is arranged on the cold side of at least one thermoelectric module;
wherein the at least two heat exchangers communicate fluidically with one another via at least one common gas outlet for discharging the hot gas from the heat exchanger arrangement.

16. A vehicle comprising:
an internal combustion engine having an exhaust gas system; and
one of a heat exchanger, which cooperates with the exhaust gas system, or a heat exchanger arrangement, which cooperates with the exhaust gas system;
wherein the heat exchanger includes:
an outer pipe through which hot gas is flowable, the outer pipe extending along a longitudinal direction, defining an outer pipe interior, and including two outer pipe walls in a cross section perpendicular to the longitudinal direction;
an inner pipe arranged in the outer pipe interior, extending along the longitudinal direction, being closed on a first longitudinal end, defining an inner pipe interior, and including two inner pipe walls in the cross section perpendicular to the longitudinal direction;
a plurality of apertures in the inner pipe walls by which the inner pipe interior communicates fluidically with the outer pipe interior;
a plurality of thermoelectric modules arranged on an outer side of the outer pipe walls, each thermoelectric module having a hot side, which faces the outer pipe, and a cold side, which faces away from the outer pipe; and
at least one coolant pipe through which a coolant is flowable and which is arranged on the cold side of at least one thermoelectric module: and
wherein the heat exchanger arrangement includes at least two heat exchangers arranged on top of one another and communicating fluidically with one another via at least one common gas outlet for discharging the hot gas from the heat exchanger arrangement.

17. The heat exchanger arrangement according to claim 15, wherein:
the outer pipe is a flat pipe; and
in the cross section perpendicular to the longitudinal direction, the two outer pipe walls are located opposite one another and form two broad sides of the flat pipe.

18. The heat exchanger arrangement according to claim 17, wherein:
the inner pipe is a flat pipe;
in the cross section perpendicular to the longitudinal direction, the two inner pipe walls are located opposite one another and form two broad sides of the flat pipe; and
the apertures are arranged in a first inner pipe wall and a second inner pipe wall of the two inner pipe walls.

19. The heat exchanger arrangement according to claim 18, wherein a first outer pipe wall of the two outer pipe walls faces the first inner pipe wall in the cross section perpendicular to the longitudinal direction, and a second outer pipe wall of the two outer pipe walls faces the second inner pipe wall.

20. The heat exchanger arrangement according to claim 15, wherein:
the at least one coolant pipe includes at least a first coolant pipe and at least a second coolant pipe; and
wherein the at least one first coolant pipe is arranged on the cold side of the at least a first thermoelectric module, and the at least one second coolant pipe is arranged on the cold side of at least a second thermoelectric module.
